(19) United States
(12) Patent Application Publication
(10) Pub. No.: US 2006/0281257 A1
(43) Pub. Date: Dec. 14, 2006

(54) Stack gate structure of flash memory device and fabrication method for the same

(75) Inventor: Jae Yuhn Moon, Chcongju-si (KR)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Gangnam-gu (KR)

(21) Appl. No.: 11/320,613

(22) Filed: Dec. 30, 2005

(30) Foreign Application Priority Data
Jun. 13, 2005 (KR) 10-2005-0050330

(51) Int. Cl. H01L 21/336

(52) U.S. Cl. 438/261; 257/314

(57) ABSTRACT

A nonvolatile memory device has a floating gate with its top and side surfaces covered by ONO film to improve the data retention of the floating gate. The ONO film has upper and lower silicon dioxide layers interposed by silicon nitride layer thinner than the oxide layers. A method includes the steps of forming a tunnel oxide layer on a silicon substrate, depositing a first polysilicon film on the tunnel oxide layer, patterning the first polysilicon film to form a floating gate, depositing oxide-nitride-oxide (ONO) film on the substrate surface to cover top and side surfaces of the floating gate, depositing a second polysilicon film on the ONO film, patterning the second polysilicon film to form a control gate, and selectively etching the ONO film to form an interlayer dielectric layer interposing between the floating and control gates and a sidewall spacer dielectric layer on sidewalls of the floating gate.

### CROSS REFERENCE TO RELATED APPLICATION

This application claims the benefit of Korean Application No. 10-2005-0050330, filed on Jun. 13, 2005, which is hereby incorporated by reference in its entirety.

### BACKGROUND OF THE INVENTION

1. Field of the Invention

The present invention relates to flash memory technologies. More specifically, the present invention relates to a stack gate structure having oxide-nitride-oxide (ONO) layer on its sidewalls to improve data retention characteristics of the floating gate and a method for fabricating such a stack structure in flash type nonvolatile memory devices.

2. Description of the Related Art

Flash memory is one of most prominent nonvolatile memory devices and takes advantages of small cell size of electrically programmable read only memory (EPROM) and electrical erase feature of EEPROM. The flash memory, which is capable of retaining the stored data without continued supply of electrical power, is widely employed as nonvolatile memories in various electronic products such as IC cards, hand-held computers, mobile telephones, digital televisions, digital camcorders, digital cameras, personal digital assistances (PDAs), game machines and MP3 players.

The flash memory typically has a stacked gate structure of a floating gate and a control gate. The floating gate, which is placed between the control gate and the semiconductor substrate, is isolated by a tunnel oxide layer. Electrons trapped into the floating gate modify the threshold voltage of the transistor. Electrons are trapped in the floating gate by Fowler-Nordheim tunneling or hot electron injection (HCI) through the tunnel oxide. Electrons are removed or erased from the floating gate by Fowler-Nordheim tunneling.

FIGS. 1a to 1f are cross-sectional views of the stacked gate used in conventional flash memory device.

Referring to FIG. 1a, a tunnel oxide layer 12 is formed on a silicon substrate 11 in which active regions are defined by isolation regions (not shown).

Referring to FIG. 1b, a first polycrystalline silicon 13 used for a floating gate is deposited on the tunnel oxide layer 12.

Then, as shown in FIG. 1c, an ONO layer 14 used for an interlayer dielectric layer is deposited on the first polysilicon 13. The ONO layer 14 comprises triple layered capacitor structure of silicon oxide, silicon nitride and silicon oxide, and is mainly used for improving the coupling ratio.

Referring to FIG. 1d, a second polysilicon 15 used for a control gate is deposited on the ONO layer 14.

Referring to FIG. 1e, the first and second polysilicon 13 and 15 and the ONO layer 14 are patterned to form a stack gate structure 16 consisting of the floating gate 13a, interlayer dielectric 14a and control gate 15a.

Referring to FIG 1f, spacer oxide layers 17 are formed on sidewalls of the stack gate 16.

The conventional stack gate 16 may experience degradation of retention feature because the sidewalls of the stack gate 16 are covered by only the spacer oxide layer 17. The retention feature of the flash memory device means an ability to retain the trapped electrons into the floating gate 13a through the tunnel oxide layer 12. When the trapped electrons escape from the floating gate without an erase command, the memory cell loses its data, which results in fatal error in the operation of memory devices. The spacer layer 17, which is made of oxide having poor dielectric constant, may cause the degradation of data retention in flash memory cells.

### SUMMARY OF THE INVENTION

It is, therefore, an object of the present invention to provide a stack gate structure of flash memory, which can improve the data retention characteristics of a floating gate, and a fabrication method thereof.

To achieve the above objects, the present invention provides a nonvolatile memory device that has a floating gate with its top and side surfaces covered by ONO film to improve the data retention feature of the floating gate. The ONO film has upper and lower silicon dioxide layers interposed by silicon nitride layer thinner than the oxide layers.

In an aspect of the present invention, method for fabricating a stack gate in a flash memory device, comprising the steps of: forming a tunnel oxide layer on a silicon substrate; depositing a first polysilicon film on the tunnel oxide layer; patterning the first polysilicon film to form a floating gate; depositing oxide-nitride-oxide (ONO) film on the substrate surface to cover top and side surfaces of the floating gate; depositing a second polysilicon film on the ONO film; patterning the second polysilicon film to form a control gate; and selectively etching the ONO film to form an interlayer dielectric layer interposing between the floating and control gates and a sidewall spacer dielectric layer on sidewalls of the floating gate.

The ONO film can be formed by LPCVD including the steps of forming the oxide layers by using N₂O gas of 20 sccm to 80 sccm and dichlorosilane (DCS, SiH₂Cl₂) gas of 10 sccm to 40 sccm under 700° C. to 900° C. temperature and 400 mTorr to 500 mTorr pressure; and forming the nitride layer by using NH₃ gas of 300 sccm to 2,000 sccm and DCS gas of 30 sccm to 1,500 sccm under 700° C. to 900° C. temperature and 400 mTorr to 500 mTorr pressure.

In the formation of the control gate, the second polysilicon is etched in high etch selectivity condition of polysilicon to oxide, which ranges from e.g., 500:1 to 1,000:1 by using HBr gas of 50 sccm to 160 sccm and O₂ gas of 1 sccm to 5 sccm under pressure of 1 mTorr to 100 mTorr with electrical power of 400 W/150 W.

These and other aspects of the invention will become evident by reference to the following description of the invention, often referring to the accompanying drawings.

### BRIEF DESCRIPTION OF DRAWINGS

FIGS. 1a to 1f are cross-sectional views of the stacked gate used in conventional flash memory device.

FIGS. 2a to 2g are cross-sectional views for illustrating the stack gate structure of flash memory device according to the present invention and fabrication method thereof.

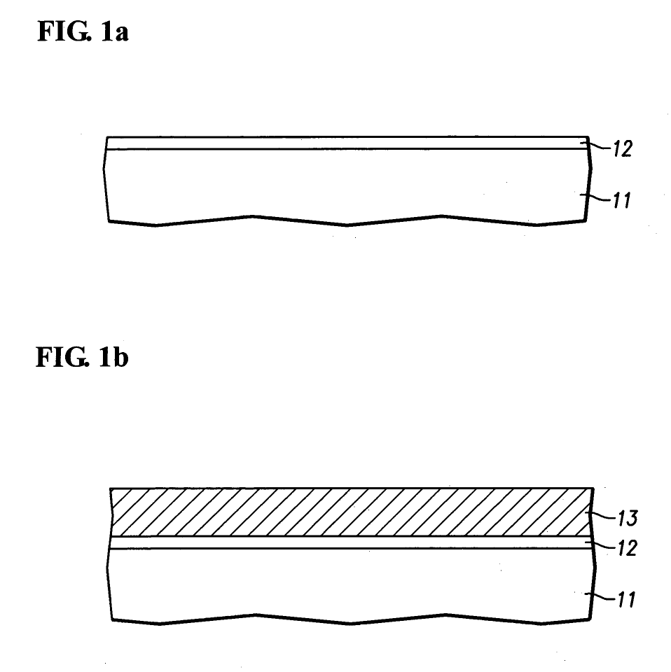

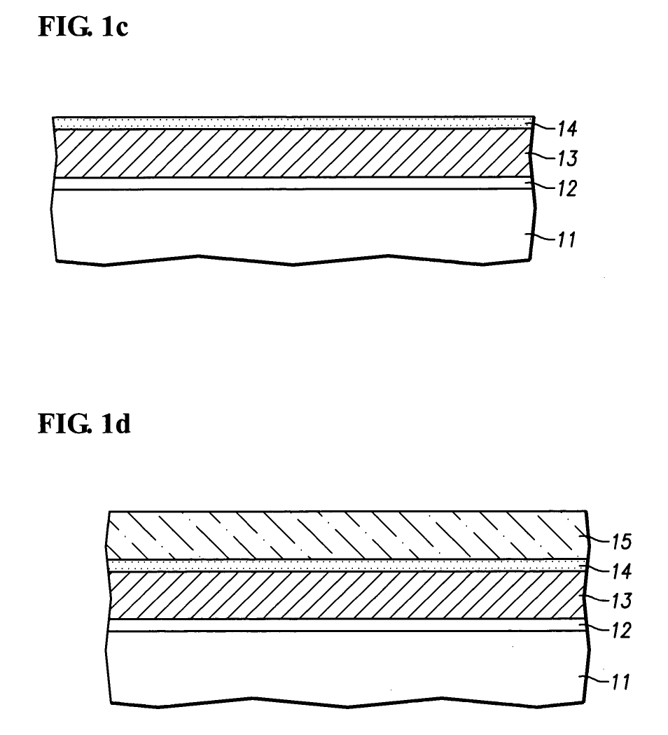

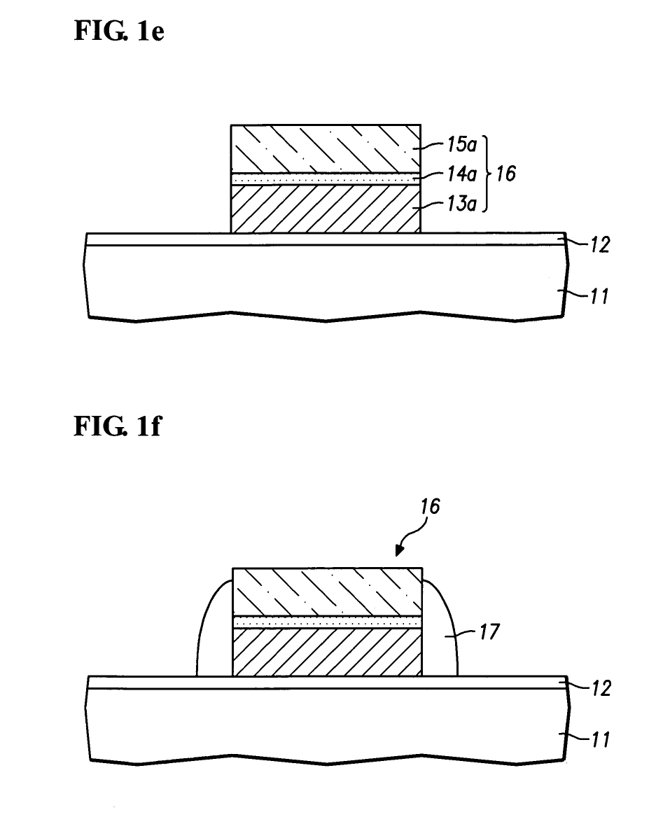

### DETAILED DESCRIPTION OF THE INVENTION

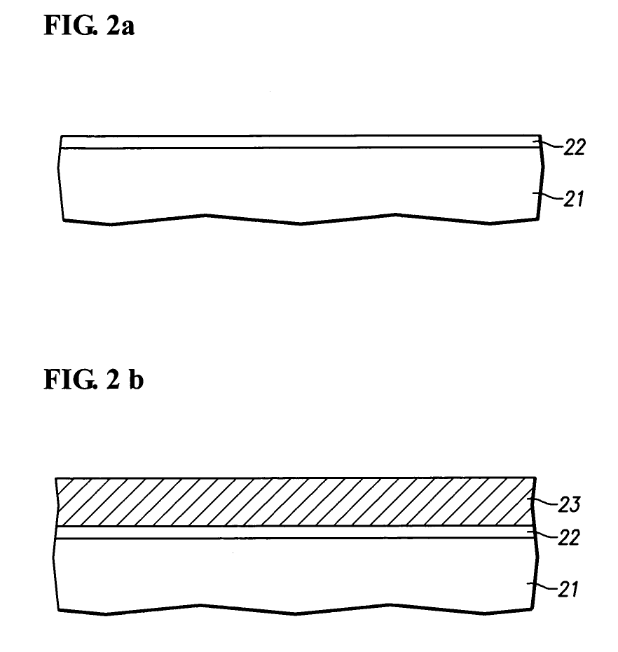

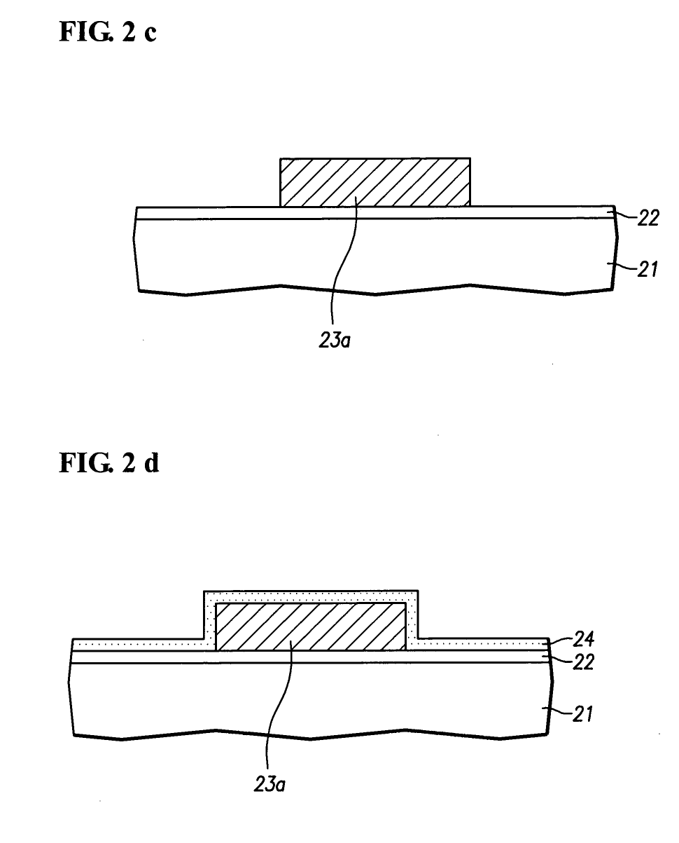

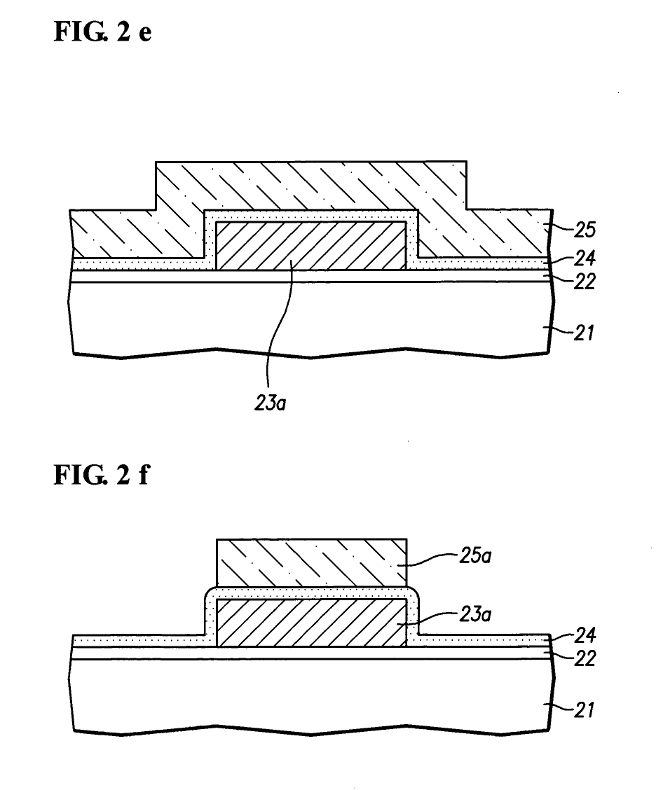

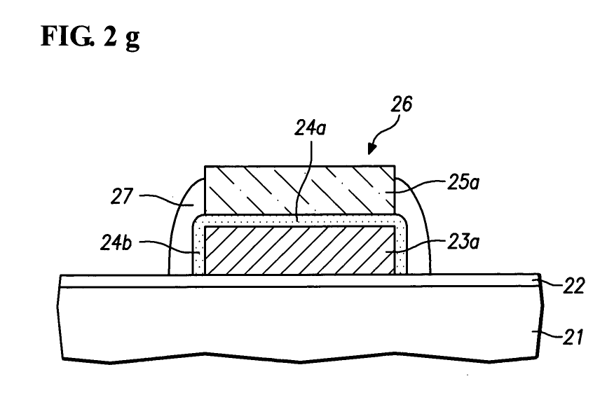

Hereinafter, embodiments of a nonvolatile memory device and fabrication method thereof, according to the present invention, will be described with reference to FIGS. 2a to 2g.

FIGS. 2a to 2g are cross-sectional views for illustrating the stack gate structure of flash memory device according to the present invention and fabrication method thereof.

Referring to FIG. 2a, a tunnel oxide layer 22 is formed on a silicon substrate 21 in which active regions defined by isolation regions (not shown) are formed. The tunnel oxide layer 22 can be grown by conventional wet oxidation and thermal treatment.

Referring to FIG. 2b, a first polycrystalline silicon 23 used for a floating gate is deposited on the tunnel oxide layer 22. The first polysilicon 23 can be deposited by low pressure chemical vapor deposition (LPCVD) technique.

Referring to FIG. 2c, the first polysilicon 23 is selectively etched to form a floating gate 23a. In the conventional process, the first polysilicon is patterned together with the ONO and second polysilicon layers. However, in the present invention, the first polysilicon 23 is patterned before the ONO and second polysilicon layers are deposited.

Referring to FIG. 2d, an ONO layer 24 is deposited on the entire substrate surface. Therefore, the ONO layer 24 completely encloses the floating gate 23a by covering the top and side surfaces of the floating gate 23a.

In an embodiment of the present invention, the ONO layer 24 is formed by stacking sequentially lower silicon oxide layer, silicon nitride layer and upper silicon oxide layer. The stacked triple layers can be replaced by oxide and nitride bilayer dielectric, oxide-titanium oxide bilayer dielectric (SiO₂ and Ti₂O₅), or silicon oxide-titanium oxide/silicon oxide trilayer dielectric.

When the ONO layer 24 is silicon oxide-silicon nitride-silicon oxide triple layers, it is preferable to make the nitride layer to be thinner than the lower and upper oxide layers.

The deposition of the ONO layer 24 as explained with reference to FIG. 2d is performed by e.g., LPCVD method. In an embodiment of the present invention, the top and bottom oxides of the ONO layer are formed by source gas including N₂O of 20 sccm to 80 sccm and dichlorosilane (DCS, SiH₂Cl₂) gas of 10 sccm to 40 sccm under 700° C. to 900° C. temperature and 400 mTorr to 500 mTorr pressure. The nitride layer of the ONO layer is formed by source gas including NH₃ gas of 300 sccm to 2,000 sccm and DCS gas of 30 sccm to 1,500 sccm under 700° C. to 900° C. temperature and 400 mTorr to 500 mTorr pressure. The thicknesses of the oxide and nitride layers are about 50 Å and 100 Å, respectively.

Referring to FIG. 2e, a second polysilicon 25 used for a control gate is deposited on the ONO layer 24. The deposition of the second polysilicon 25 is performed by e.g., LPCVD.

Referring to FIG. 2f, the second polysilicon 25 is etched or patterned to form the control gate 25a. In the etching of the second polysilicon 25, conditions for high etch selectivity of polysilicon relative to oxide (i.e., the polysilicon is etched at the much higher rate than oxide) are preferable. For instance, when HBr gas of 50 sccm to 160 sccm and O₂ gas of 1 sccm to 5 sccm are used for etching gas under pressure of 1 mTorr to 100 mTorr with electrical power of 400 W/150 W, the selectivity of polysilicon to oxide ranges from 500:1 to 1,000:1. Therefore, the control gate 25a is formed without giving damages to the ONO layer 24 on the sidewalls of the floating gate 23a.

Referring to FIG. 2g, the ONO layer 24 is selectively etched to form an interlayer dielectric layer 24a interposing between the floating gate 23a and the control gate 25a and spacer dielectric layers 24b on the sidewalls of the floating gate 23a. Therefore, a stack gate 26 including the floating gate 23a, interlayer dielectric layer 24a, control gate 25a and spacer dielectric layer 24b is obtained. It is possible to form additional spacer oxide layers 27 on the spacer dielectric layer 24b.

The ONO layer constituting the sidewall spacer dielectric layer 24b has higher dielectric constant than the conventional silicon dioxide film, and hence the floating gate 23a enclosed by the ONO layer exhibits highly improved data retention feature.

According to the present invention, no additional processing steps are required for improving the data retention characteristics, because the ONO layer which is interposed between the floating and control gate and employed as an interlayer dielectric can be also used in the formation of the sidewall spacer dielectric layer.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A stack gate structure in a flash memory device, comprising:
a tunnel oxide layer formed on a silicon substrate;
a floating gate formed on the tunnel oxide layer and made of a first polysilicon film;
an interlayer dielectric layer formed on the floating gate and made of an oxide-nitride-oxide (ONO) film;
a control gate formed on the interlayer dielectric layer and made of a second polysilicon film; and
a sidewall spacer dielectric layer formed on sidewalls of the floating gate and made of said ONO film.

2. The stack gate structure of claim 1, wherein an additional spacer oxide layer is formed on the sidewall spacer dielectric layer.

3. The stack gate structure of claim 1, wherein the interlayer dielectric layer and the sidewall spacer dielectric layer cover top and side surfaces of the floating gate.

4. The stack gate structure of claim 1, wherein the oxide of the ONO film is silicon dioxide and the nitride of the ONO film is silicon nitride.

5. The stack gate structure of claim 1, wherein the oxide is thicker than the nitride.

6. A method for forming a stack gate in a flash memory device, said method comprising the steps of:
forming a tunnel oxide layer on a silicon substrate;
depositing a first polysilicon film on the tunnel oxide layer;
patterning the first polysilicon film to form a floating gate;
depositing an oxide-nitride-oxide (ONO) film on the substrate surface to cover top and side surfaces of the floating gate;
depositing a second polysilicon film on the ONO film;
patterning the second polysilicon film to form a control gate; and
selectively etching the ONO film to form an interlayer dielectric layer interposing between the floating and control gates and a sidewall spacer dielectric layer on sidewalls of the floating gate.

7. The method of claim 6, wherein the deposition of the ONO film is carried out by low power chemical vapor deposition (LPCVD).

8. The method of claim 6, wherein the LPCVD includes the steps of:
forming the oxide layers by using N₂O gas of 20 sccm to 80 sccm and dichlorosilane (DCS, SiH₂Cl₂) gas of 10 sccm to 40 sccm under 700° C. to 900° C. temperature and 400 mTorr to 500 mTorr pressure; and
forming the nitride layer by using NH₃ gas of 300 sccm to 2,000 sccm and DCS gas of 30 sccm to 1,500 sccm under 700° C. to 900° C. temperature and 400 mTorr to 500 mTorr pressure.

9. The method of claim 6, wherein the step for patterning the second polysilicon film to form the control gate is carried out with high etch selectivity of the polysilicon to oxide.

10. The method of claim 9, wherein the etch selectivity ranges from 500:1 to 1,000:1.

11. The method of claim 9, wherein the etching of polysilicon is carried out by using HBr gas of 50 sccm to 160 sccm and O₂ gas of 1 sccm to 5 sccm are used for etching gas under pressure of 1 mTorr to 100 mTorr with electrical power of 400 W/150 W.

12. The method of claim 6, wherein the oxide of the ONO film is silicon dioxide and the nitride of the ONO film is silicon nitride.

13. The method of claim 6, wherein the oxide is thicker than the nitride.
